(19) United States
(12) Patent Application Publication
(10) Pub. No.: US 2026/0338899 A1
(43) Pub. Date: Oct. 29, 2026

(54) Ascertaining Magnetic Resonance Signal Components from Interference Signal Sources

(71) Applicant: Siemens Healthineers AG, Forchheim (DE)

(72) Inventors: Hans-Peter Fautz, Forchheim (DE); Sebastian Probst, Erlangen (DE)

(73) Assignee: Siemens Healthineers AG, Forchheim (DE)

(21) Appl. No.: 19/657,077

(22) Filed: Apr. 24, 2026

(30) Foreign Application Priority Data
Apr. 25, 2025 (DE) 10 2025 116 063.5

(51) Int. Cl. G01R 33/56; G01R 33/483

(52) U.S. Cl. CPC G01R 33/5608; G01R 33/4838

(57) ABSTRACT

Techniques are provided for ascertaining magnetic resonance (MR) signal components from interference signal sources. The techniques include loading an MR signal which was acquired by a plurality of antenna elements of a magnetic resonance system from an examination volume of an examination object located within the magnetic resonance system in which a channel is assigned to each antenna element. It is also determined, based on a selected signal model and at least one selected cost function, whether the MR signal contains signal components assignable to interference signal sources, and information is output if signal components assignable to interference signal sources have been ascertained. Signal components assigned to interference signal sources may also be stored. The techniques enable the implementation of various measures to ensure the quality of MR images reconstructed from acquired MR signals and/or the performance of the magnetic resonance system used.

### CROSS-REFERENCE TO RELATED APPLICATIONS

This application claims priority to Germany patent application no. DE 10 2025 116 063.5, filed on Apr. 25, 2025, the contents of which are incorporated herein by reference in their entirety.

### TECHNICAL FIELD

The disclosure relates to the classification of magnetic resonance signal components and, in particular, to the classification of magnetic resonance signal components according to different signal sources.

### BACKGROUND

Magnetic resonance (MR) imaging is a well-known technique for generating images of the interior of an examination object. In simple terms, for this purpose the examination object is positioned in a magnetic resonance device in a comparatively strong static homogeneous main magnetic field, also referred to as the B0 field, with field strengths of 0.2 tesla to 7 tesla and more, such that its nuclear spins align along the main magnetic field. To trigger nuclear spin resonances that can be measured as signals, radio-frequency excitation pulses (RF pulses) are irradiated into the examination object, the resulting nuclear spin resonances are measured as so-called k-space data by means of coils configured for reception and used as the basis for reconstructing MR images or ascertaining spectroscopy data. The alternating magnetic field generated by the excitation pulses irradiated by means of at least one transmit coil is also referred to as the B1 field. For spatial encoding of the measurement data, rapidly switched magnetic fields (gradients) are superimposed on the main magnetic field. A schedule describing a temporal sequence of RF pulses to be irradiated and gradients to be switched is referred to as a pulse sequence (schedule) or sequence for short. The acquired measurement data is digitized and stored as complex numerical values in a k-space matrix. A corresponding MR image can be reconstructed from the k-space matrix populated with values, for example, by means of a multidimensional Fourier transform.

The required RF pulses are irradiated into the examination object by means of MR transmit coils. The resulting nuclear spin resonances are received by MR receive coils.

It is known to use a so-called “body coil” for irradiating the RF pulses; this surrounds the patient bore of a magnetic resonance system along its circumferential surface. Furthermore, so-called local coils are known which can be arranged in close proximity to an examination object to be examined; these are typically configured as pure RF receive coils, but may also be configured as RF transmit coils or combined RF transmit/receive coils (Tx/Rx) and frequently comprise multiple antenna elements, each associated with a respective channel on which a portion of a corresponding MR signal is measured.

### SUMMARY

MR signals and MR images reconstructed therefrom are unfortunately frequently affected by artifacts that degrade image quality. Such artifacts may arise due to insufficient or improperly executed excitation of the nuclear spins and/or incomplete reception of the resulting MR signals. Furthermore, artifacts can arise due to signal components of the measured MR signal that are assigned to an incorrect position, for example due to incorrect spatial encoding, even though they originated elsewhere. Such artifacts can also include motion artifacts, which, due to motion within the examination volume, typically assign signals generated within the examination volume to an incorrect position.

In addition, artifacts can arise from signal components of the measured MR signal that are incorrectly assigned to the desired examination volume, even though they originated elsewhere, for example outside the examination volume. Such artifacts can include so-called third-arm artifacts, which are unintentionally excited outside, but close to, the desired examination volume and are erroneously regarded as having originated within the examination volume. Moreover, signal components may be measured that are unrelated to the examination volume but interfere with the desired MR signal, for example because they are located within the measured frequency band. Artifacts caused by such interfering external signals can, for example, include so-called spike artifacts resulting from voltage spikes in the gradient unit of a magnetic resonance system, or so-called zipper artifacts caused by external RF sources coupling into the measured MR signal. If the contribution of an undesired signal component is small, the resulting effect is generally referred to as noise rather than as an artifact.

Quality assurance of MR images is typically performed manually by a user, for example a radiologist. Herein, the detection of artifacts is highly dependent on the experience of the user. Factors to be considered include the clinical likelihood of an artifact being real and the ability to understand the cause of the artifact in order to identify it and potentially link it to the associated signal source. Consequently, this manual approach is highly error-prone and time-consuming. One approach for automated image quality control consists in evaluating each output image based on specific general quality criteria and notifying the user that there is a potential problem. However, this purely image-based approach does not aim to identify artifacts based on the measured MR signals, e.g. if such artifacts originate outside the volume of interest, but is merely used to check existing image data. Moreover, there is a high susceptibility to errors, for example because a significant amount of information may already have been lost if artifacts are evaluated only in image space, for example after one or more filters have been applied to the MR image.

The disclosure is based on the object of making such undesirable signal components in measured MR signals detectable to at least indicate potential contamination with artifacts or noise caused by the unwanted signal components, e.g. to improve the achievable image quality and/or performance of magnetic resonance systems. The object is achieved by the various embodiments as discussed herein, including the claims.

A method according to the disclosure for ascertaining magnetic resonance (MR) signal components from interference signal sources comprises the following steps:
loading an MR signal which was acquired by a plurality of antenna elements of a magnetic resonance system from an examination volume of an examination object located within the magnetic resonance system, wherein a channel is assigned to each antenna element,
ascertaining, based on a selected signal model and at least one selected cost function, whether the MR signal contains signal components assignable to interference signal sources,
outputting information if signal components assignable to interference signal sources have been ascertained and/or storing signal components that are assigned to interference signal sources.

Ascertaining according to the disclosure signal components assignable to interference signal sources and outputting or storing corresponding information makes it possible to implement various measures to ensure the quality of MR images reconstructed from acquired MR signals and/or the performance of the magnetic resonance system used.

An ascertaining unit according to the disclosure is embodied to execute a method according to the disclosure.

A magnetic resonance system according to the disclosure comprises a magnet unit, a gradient unit, a radio-frequency unit and a control facility embodied to perform a method according to the disclosure with an ascertaining unit.

A computer program according to the disclosure implements a method according to the disclosure on a control facility when it is executed on the control facility or on an ascertaining unit when it is executed on the ascertaining unit. For example, the computer program comprises instructions which, when the program is executed by a control facility, for example a control facility of a magnetic resonance system, or an ascertaining unit cause said facility or unit to execute a method according to the disclosure. The control facility or the ascertaining unit can be present in the form of a computer.

Herein, the computer program can also be present in the form of a computer program product that can be loaded directly into a memory of a control facility or an ascertaining unit with program code means for executing a method according to the disclosure when the computer program product is executed in a computing unit or a computing unit of a computing system of the control facility.

A computer-readable storage medium according to the disclosure comprises instructions which, when executed by a control facility, for example a control facility of a magnetic resonance system, or by an ascertaining unit, cause said facility or unit to execute any of the methods according to the disclosure.

The computer-readable storage medium can be present in the form of an electronically readable data carrier comprising electronically readable control information stored thereon which comprises at least one computer program according to the disclosure and is configured such that, when the data carrier is used in a control facility of a magnetic resonance system or in an ascertaining unit, it performs any of the methods according to the disclosure.

The advantages and explanations relating to the method embodiments also apply analogously to the ascertaining unit embodiments, the magnetic resonance system embodiments, the computer program product embodiments, and the electronically readable data carrier embodiments.

### BRIEF DESCRIPTION OF THE DRAWINGS

Further advantages and details of the present disclosure will become apparent from the exemplary embodiments described below and with reference to the drawings. The examples listed do not constitute a restriction of the disclosure. The drawings show:

FIG. 1 illustrates a schematic flowchart of an example method for classifying MR signal components according to the disclosure;

FIG. 2 illustrates a schematic representation of an example magnetic resonance system according to the disclosure.

### DETAILED DESCRIPTION

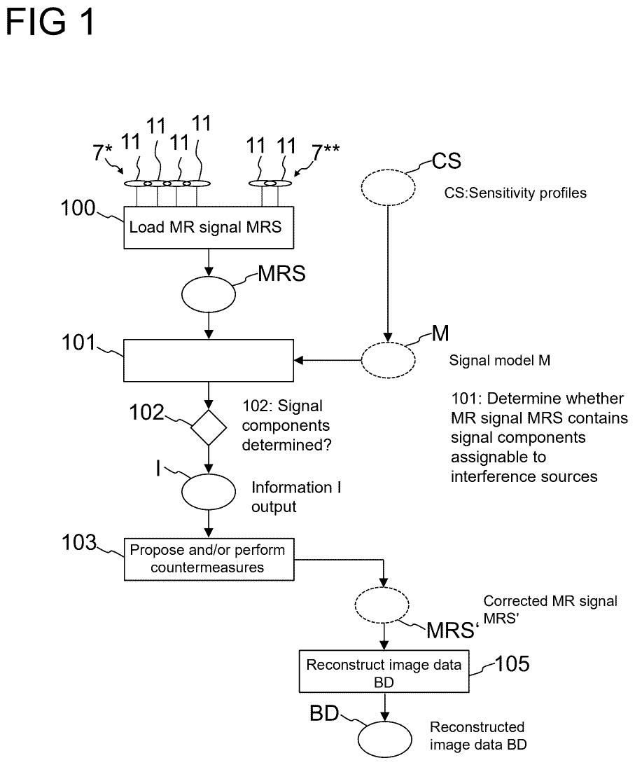

FIG. 1 is a schematic flowchart of a method according to the disclosure for ascertaining MR signal components from interference signal sources.

As shown in FIG. 1, an MR signal MRS is loaded (Block 100). This signal may be acquired for example using a plurality of antenna elements 11 of a magnetic resonance system 1 from an examination volume V of an examination object U located within the magnetic resonance system 1, wherein a channel is assigned to each antenna element 11. Herein, the antenna elements 11 can for example comprise antenna elements 11 of one or more local coils 7′, 7″ of the magnetic resonance system 1 used. The antenna elements may alternatively be referred to herein simply as “antennas.”

Herein, MR signals MRS may have been acquired in any suitable manner, including in a conventional manner.

Based on a selected signal model M and at least one selected associated cost function, it is then ascertained whether the MR signal MRS contains signal components assignable to interference signal sources (Block 101). A query 102 may be issued to check or determine whether signal components that are actually assignable to interference signal sources of the MR signal have been ascertained. If this is the case, corresponding information I can be output and/or the signal components assignable to interference signal sources can be stored, for example for further processing.

A selected signal model M makes certain assumptions regarding the composition of an MR signal and models an MR signal in accordance with the assumptions made. A signal model M may, for example, comprise a matrix, which, for example, comprises a column or row for each antenna element 11.

A selected signal model M may, for example, assume at least one point-like interference signal source. Herein, the selected signal model M may assume that at least one point-like interference signal source is located outside the examination volume V. Such point-like interference signal sources can further be assumed to be independent interference signal sources.

A selected signal model M may assume a sum of continuous signal sources within the examination volume V for an interference-free MR signal.

Signal components from different channels differ from one another according to the sensitivity profiles of the corresponding antenna elements. Furthermore, the position of a signal source relative to a measuring antenna element also influences the measured signal component.

A selected signal model M can take into account known background information, e.g. as at least one cost function, regarding an acquired MR signal and/or possible interference signal sources. For example, a selected signal model may take into account sensitivity profiles CS of the antenna elements 11. Such sensitivity profiles CS are typically measured anyway when acquiring MR signals, for example in the context of so-called pre-scans, since they are often used in the reconstruction of MR images from the measured MR signals, e.g. when using parallel imaging techniques. In this context, such sensitivity profiles are also referred to as coil sensitivity data. A selected signal model M may use such sensitivity data CS as transfer functions from assumed signal sources to assumed measured signal components, for example to check data consistency.

A possible signal model M may, for example, assume the examination volume V as a distribution of point-like signal sources (sᵢₙ) and the sensitivity profiles CS of the antenna elements as associated transfer functions h_{c}, as well as interference signal sources (sₑₓₜ), which are, for example, assumed to be located at a sufficient distance from the examination volume V, and are therefore assumed to be point-like. Other possible signal models M may make different assumptions.

In the example mentioned, a signal s_{c} measured at an antenna element may, for example, be modeled as:

$${s}_{c i} = IFFT ( {\sum }_{j}^{V} {s}_{i n , j} \cdot {h}_{c , i , j} ) + {\sum }_{k}^{N} {s}_{ext , k} * {h}_{c , i , k} ,$$

where j represents an index representing the position in the examination volume V, i represents an index representing the antenna element and k represents an index representing N assumed (external) interference signal sources.

This allows a linear problem to be formulated (over all antenna elements) as:

s̅_{c}=Hs̅

where H represents the mixing matrix of the signal model M and s̅ are separate signal components. Such linear problems may, for example, be solved using ICA.

If the problem can no longer be represented as pure matrix multiplication, it can also be formulated as a nonlinear problem according to:

s̅_̅{̅c̅}̅=H(s̅)

where H is a mixing function of the signal model M and s̅ are separate signal components. Such nonlinear problems can be solved using a machine-learning approach, for example an approach based on so-called U-Nets.

To separate the signal components, it is necessary to determine an estimate of H and of its inverse Ĥ. To this end, a corresponding optimization problem can be solved as a signal model M.

Ascertaining signal components assignable to interference signal sources may comprise ascertaining the Gaussian nature of signal components. According to the central limit theorem, a sum of independent signal components tends to exhibit a stronger Gaussian nature than signals from independent signal sources. Accordingly, it can be expected that signal components originating from signal sources within a contiguous examination volume V tend to follow a Gaussian distribution, whereas signal components originating from independent (interference) signal sources are not expected to follow a Gaussian distribution. This can be utilized to classify signal components with a non-Gaussian distribution as signal components assignable to an interference signal source. Such a check of the Gaussian nature can be incorporated into a selected signal model M as a cost function.

Ascertaining signal components assignable to interference signal sources may comprise ascertaining the similarity of signal components of the MR signal MRS. Signal components originating from signal sources in a contiguous examination volume V can be expected to exhibit greater similarity than signal components originating from independent (interference) signal sources. This may be utilized to classify signal components for which a similarity value with other signal components exceeds a threshold value as signal components assignable to an interference signal source. Such a similarity check may be incorporated into a selected signal model M as a cost function. A conceivable similarity value is, for example, mutual information—as known from information theory—that decreases as the signal components become less similar.

Additionally or alternatively, ascertaining signal components assignable to interference signal sources can comprise ascertaining a distance of a point-like signal source from the examination volume. If, for example, based on the selected signal model M, the MR signal MRS contains signal components originating from signal sources located outside the examination volume V, it can be assumed that these signal components are assignable to interference signal sources. Ascertaining the distance of a signal source of the MR signal in this way can be incorporated into the selected signal model M as a cost function. Ascertaining a distance in this way may, for example, be based on an intensity or energy contribution of the signal components of the MR signal. The further a signal source of a signal component is from a receiving antenna element, the lower its intensity or energy contribution becomes.

Furthermore, it is conceivable for ascertaining interference signal sources to comprise the use of independent component analysis (ICA). ICA methods may be used to separate signal sources originating from different spatial distances and spatial angles. It is possible to select a signal model M that may be combined with an ICA method.

Ascertaining signal components assignable to interference signal sources may also comprise assigning the respective interference signal sources to one of at least two types of interference signal sources. For example, a signal component assigned to an interference signal source may be analyzed with respect to its spectrum and/or its spatiotemporal behavior, e.g. within analysis windows that define a time frame. This may, for example, be done using a neural network-based method for artifact detection as described in EP4332883A1. The most common examples of disruptive external interference signal sources are spikes, which typically manifest as short-duration broadband signals that lead to wave-like spike artifacts in reconstructed MR images, and RF artifacts, and which typically manifest as long-duration narrowband signals that lead to streaks or regionally amplified noise in a reconstructed MR image. For example, therefore the analysis of the spatiotemporal behavior of a signal component may be used to classify an associated interference signal source as an external RF transmitter or as a spike.

It is also possible to determine whether an artifact is triggered by a signal component from an interference signal source inside or outside the examination volume V and whether an interference signal source located outside the examination volume V originates from an external RF transmitter or was generated by spins of the examination object accidentally excited outside the examination volume (“third-arm artifact”). Thus, a distinction can be made between internal interference signal sources and external interference signal sources as types of interference signal sources, and, where applicable, additionally between extraneous external interference signal sources (outside the examination object) and incorrectly excited external interference signal sources.

In an embodiment, the presence of interference may be output as information I. Such information I regarding the presence of interference may, for example, in itself serve as a warning and help to improve any further processing of the measured MR signal MRS or to eliminate the interference. For example, artifacts in MR images caused by external interference signal sources are often not recognizable as such in the image. However, a user who is informed about the presence of interference can, for example, search for, identify, and remove an interfering RF transmitter.

The information I output may also include the type of interference, e.g. if interference signal sources have been assigned to different types of interference signal sources. Knowing the type of interference makes it easier to eliminate.

Information I may also include the proposal and/or performance of countermeasures (Block 103). For example, if interference from an external RF transmitter is recognized, an instruction may be issued to remove the external RF transmitter from the environment of the magnetic resonance system 1. For example, if interference caused by a spike in a gradient unit of the magnetic resonance system 1 is recognized, an instruction may be issued to have the gradient unit checked, serviced or replaced, or information can be sent to a service center for the magnetic resonance system 1. Herein, the service center can respond promptly and, for example, provide a remedy by issuing servicing instructions—such as regulating the humidity—or scheduling a maintenance appointment. This also enables monitoring and/or trend analysis of the magnetic resonance system 1. For a service technician, information I including, for example, a simple visualization of identified transfer functions h_{c} could significantly facilitate the localization of an error. For example, if, during an examination of an abdomen as the examination volume V of a patient as the examination object U in which, for example, a first antenna element 11 is arranged in close proximity to the examination volume V, a service technician observes a significant increase in signal components assignable to interference signal sources in an antenna element 11 arranged further away, for example in spatial proximity to gradient connections, the service technician may infer that a spike artifact, frequently caused by gradient connections, has been generated and take appropriate remedial action.

If interference is present, a correction may also be initiated as a countermeasure, thereby enabling a corrected MR signal MRS′, in which signal components assigned to interference signal sources have been removed, to be determined. In an illustrative example, these may be removed by subtracting the ascertained signal components from the measured MR signal MRS. MR signals MRS′ corrected in this way can be used as the basis for the reconstruction of image data BD for MR images.

The loaded MR signal MRS may have been acquired with antenna elements of at least one local coil 7′, 7″ of the magnetic resonance system 1.

The loaded MR signal MRS may for example have been acquired using at least two antenna elements 11, wherein one antenna element 11 of the at least two antenna elements 11 is arranged in close proximity to the examination volume V and at least one antenna element 11 of the at least two antenna elements 11 is arranged at a minimum distance, which is, for example, as large as possible, from the examination volume V. This enables a larger spatial area to be covered by the antenna elements 11. For example, a spine coil as a local coil typically comprises a plurality of antenna elements 11 that cover a large spatial area and are therefore often not all used for a given measurement on an examination object. This makes it easy to use an antenna element 11 positioned further away from the examination volume V to acquire the MR signal MRS to increase spatial coverage for artifact detection.

The loaded MR signal MRS may also have been acquired using at least two antenna elements 11, wherein one antenna element 11 of the at least two antenna elements 11 is an antenna element 11 of a first local coil 7′ and at least one antenna element 11 of the at least two antenna elements 11 is an antenna element 11 of a further local coil 7″. The use of at least one antenna element 11 of a further local coil 7″ allows an even larger spatial area to be covered by antenna elements 11. If, for example during the acquisition of the MR signal MRS, the first local coil 7′ is arranged in close proximity to the examination volume V, a further local coil 7″ may be arranged at a slight distance from the examination volume V, for example at a minimum distance from the examination volume V, to measure signal components of the MR signal MRS from a different spatial area with the at least one antenna element 11 of the further local coil 7″.

The use of such spaced-apart antenna elements 11 of one or more local coils 7′, 7″ enables interference signal sources, e.g. external interference signal sources, to be detected more reliably and may also assist in assigning the interference signal sources to a type of interference signal source, for example by facilitating spatial localization of the interference signal.

The first local coil 7′ may, for example, be a head coil, for example for measurements where the examination volume V is located in a region of the head of a patient as the examination object U. Alternatively or additionally, the first or a further local coil 7″ may be a spine coil, as these may often be used without any additional effort when acquiring the MR signal. Spine coils are often integrated into a table L of a magnetic resonance system 1 and cover a large area thereof, so that typically antenna elements 11 of a spine coil positioned at a desired distance from the examination volume V are present.

During the reconstruction of image data BD for MR images, signal components that were measured with antenna elements 11 arranged at a distance from the examination volume V, for example antenna elements 11 of a further local coil 7″, can be discarded, so that these signal components are not taken into account during the reconstruction of image data. This may be easily achieved by not taking the corresponding channels of the spaced-apart antenna elements 11 into account during reconstruction.

Thus, the method described herein opens up various possibilities for improving image quality and/or the performance of the magnetic resonance system used, for example by removing signal components in the MR signal assigned to an interference signal source, or by informing a user that an external interference signal source is present.

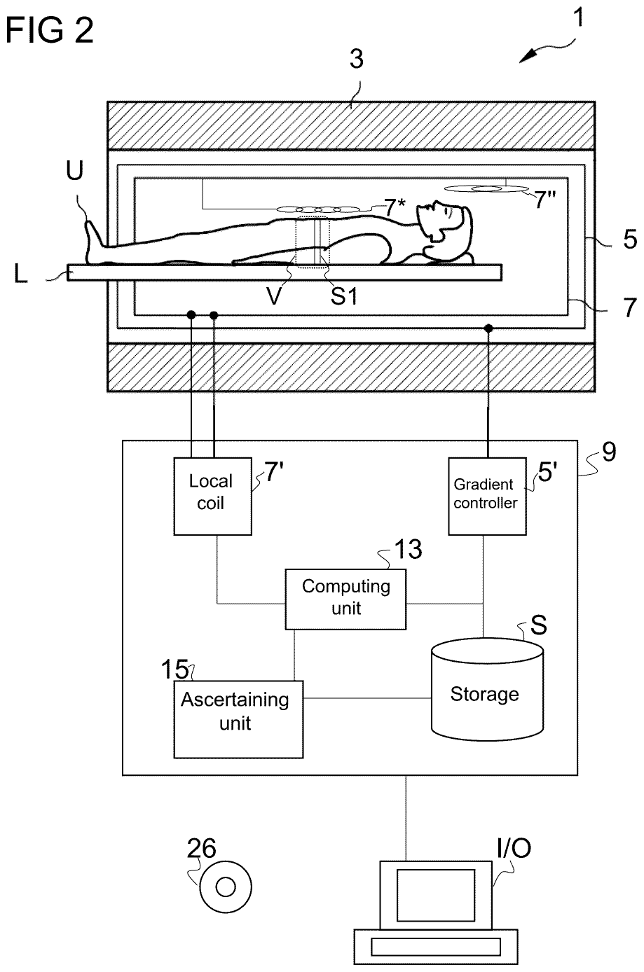

FIG. 2 is a schematic representation of a magnetic resonance system according to the disclosure 1. This comprises a magnet unit 3 (also referred to herein as a main magnet) for generating the main magnetic field, a gradient unit 5 (also referred to herein as gradient circuitry or gradient generating circuitry) for generating the gradient fields, a radio-frequency unit 7 (also referred to herein as RF circuitry) for irradiating and receiving radio-frequency signals, and a control facility 9 (also referred to herein as a controller, processing circuitry, or one or more processors) embodied to perform any of the methods according to the disclosure.

FIG. 2 is provides a schematic representation of these various subunits of the magnetic resonance system 1. The radio-frequency unit 7 may also include a plurality of subunits and, for example, comprise a plurality of coils. The radio-frequency unit 7 may for instance comprise a body coil that is permanently integrated into the magnetic resonance system 1, and may in turn comprise a plurality of antenna elements. Furthermore, the radio-frequency unit 7 may comprise one or more different local coils 7′, 7″ that can be configured either solely to transmit radio-frequency signals or solely to receive the triggered radio-frequency signals or to do both, and which themselves can comprise a plurality of antenna elements 11 and associated coil channels.

To examine an examination object U, for example a patient or also a phantom, the object can be introduced into the measurement volume of the magnetic resonance system 1 on a table L. The slice S1 represents an example of a measurement volume in an examination volume V of the examination object U from which echo signals can be acquired and captured as measurement data.

The control facility 9 is used to control the magnetic resonance system 1 and may for example control the gradient unit 5 via a gradient controller 5′ and the radio-frequency unit 7 via a radio-frequency transmit/receive controller 7′. Herein, the radio-frequency unit 7 may comprise a plurality of channels on which signals can be transmitted or received.

Together with its radio-frequency transmit/receive controller 7′, the radio-frequency unit 7 may be responsible for generating and irradiating (transmitting) an alternating radio-frequency field to manipulate the spins in an area of the examination object U to be manipulated. Herein, the center frequency of the alternating radio-frequency field, also referred to as the B1 field, is typically set as closely as possible to the resonant frequency of the spins to be manipulated. Deviations of the center frequency from the resonant frequency are referred to as off-resonance. To generate the B1 field, currents controlled by the radio-frequency transmit/receive controller 7′ are applied to the RF coils in the radio-frequency unit 7.

Furthermore, the control facility 9 comprises an ascertaining unit 15 (also referred to herein as ascertaining circuitry, processing circuitry, or one or more processors) for ascertaining signal components assignable to interference signal sources according to the disclosure. Overall, the control facility 9 is embodied to perform any of the methods according to the disclosure. The ascertaining unit 15 may also be embodied as a standalone ascertaining unit 15 independent of a control facility 9, but which can, for example, be connected to a control facility 9 via a signal path.

A computing unit 13 (also referred to herein as a control computer or computer) comprised by the control facility 9 is embodied to execute all the computing operations necessary for the required measurements and determinations. Intermediate results and results required for this purpose or ascertained in this process can be stored in a memory unit S of the control facility 9. Herein, the units depicted should not necessarily be understood as being physically separate units; they only represent a subdivision into functional units, which may, however, also be implemented, for example, in fewer physical units, or even in only one single physical unit.

An input/output facility (I/O) of the magnetic resonance system 1 may be used, for example, by a user to direct control commands to the magnetic resonance system and/or to display results from the control facility 9, such as, for example, image data.

Any of the methods described herein can also be implemented in the form of a computer program comprising instructions that execute any of the described methods on a control facility 9. Likewise, a computer-readable storage medium may be provided comprising instructions that, when executed by a control facility 9 of a magnetic resonance system 1, cause the system to execute the any of the methods described herein.

Independent of the grammatical term usage, individuals with male, female or other gender identities are included within the term.

The various components described herein may be referred to as “units” or “elements.” As noted above, such components may be implemented via any suitable combination of hardware and/or software components as applicable and/or known to achieve the intended respective functionality. This may include mechanical and/or electrical components, processors, processing circuitry, or other suitable hardware components configured to execute instructions or computer programs that are stored on a suitable computer readable medium. Regardless of the particular implementation, such units and elements, as applicable and relevant, may alternatively be referred to herein as “circuitry,” “processors,” or “processing circuitry,” or otherwise as designated herein.

What is claimed is:

1. A method for determining magnetic resonance (MR) signal components from interference signal sources, comprising:
acquiring, via a plurality of antennas of a magnetic resonance system, an MR signal from an examination volume of an examination object located within the magnetic resonance system,
wherein a channel is assigned to each of the plurality of antennas;
determining, based on a selected signal model and a selected cost function, whether the MR signal contains signal components assignable to interference signal sources; and
in response to a determination that signal components are assignable to interference signal sources, (i) outputting information with respect to the interference signal sources, and/or (ii) storing signal components that are assigned to the interference signal sources.

2. The method as claimed in claim 1, wherein determining whether the MR signal contains signal components assignable to interference signal sources comprises determining whether signal components of the MR signal conform to a Gaussian distribution.

3. The method as claimed in claim 1, wherein determining whether the MR signal contains signal components assignable to interference signal sources comprises determining a distance between a point-like signal source and the examination volume.

4. The method as claimed in claim 1, wherein the selected signal model represents at least one point-like interference signal source.

5. The method as claimed in claim 4, wherein the selected signal model represents the at least one point-like interference signal source as being located outside the examination volume.

6. The method as claimed in claim 1, wherein the selected signal model represents a sum of continuous signal sources within the examination volume for an interference-free MR signal.

7. The method as claimed in claim 1, wherein the selected signal model represents sensitivity profiles of the antennas.

8. The method as claimed in claim 1, wherein determining whether the MR signal contains signal components assignable to interference signal sources comprises assigning respective interference signal sources to one of at least two types of interference signal sources.

9. The method as claimed in claim 1, wherein the information output with respect to the interference signal sources comprises a type of interference.

10. The method as claimed in claim 1, wherein the information output with respect to the interference signal sources comprises proposed countermeasures.

11. The method as claimed in claim 10, further comprising:
implementing the proposed countermeasures in the magnetic resonance system to correct the MR signal by removing the signal components assigned to the interference signal sources.

12. The method as claimed in claim 1, wherein the plurality of antennas comprise a first antenna of a local coil and a second antenna of a further local coil.

13. The method as claimed in claim 1, wherein a first antenna of the plurality of antennas is arranged at a first distance from the examination volume, and a second antenna of the plurality of antennas is arranged at a second distance from the examination volume different from the first distance.

14. A magnetic resonance (MR) system, comprising:
a main magnet;
a plurality of antennas configured to acquire an MR signal from an examination volume of an examination object located within the magnetic resonance system,
wherein a channel is assigned to each of the plurality of antennas; and
a controller configured to:
determine, based on a selected signal model and a selected cost function, whether the MR signal contains signal components assignable to interference signal sources; and
in response to a determination that signal components are assignable to interference signal sources, cause the MR system to (i) output information with respect to the interference signal sources, and/or (ii) store signal components that are assigned to the interference signal sources.

15. A computer-readable storage medium comprising instructions that, when executed by a controller of a magnetic resonance (MR) system, cause the MR system to determine magnetic resonance signal components from interference signal sources by:
acquiring, via a plurality of antennas of the MR system, an MR signal from an examination volume of an examination object located within the magnetic resonance system,
wherein a channel is assigned to each of the plurality of antennas;
determining, based on a selected signal model and a selected cost function, whether the MR signal contains signal components assignable to interference signal sources; and
in response to a determination that signal components are assignable to interference signal sources, (i) outputting information with respect to the interference signal sources, and/or (ii) storing signal components that are assigned to the interference signal sources.
